(19) United States
(12) Patent Application Publication
(10) Pub. No.: US 2016/0091563 A1
(43) Pub. Date: Mar. 31, 2016

(54) SCAN FLIP-FLOP

(71) Applicant: Taiwan Semiconductor Manufacturing Company Limited, Hsin-Chu (TW)

(72) Inventors: Chuang-Hao Lu, Yangmei City (TW); Nan-Hsin Tseng, Tainan City (TW); Wen-Wen Hsieh, New Taipei City (TW); Wei-Pin Changchien, Taichung City (TW)

(21) Appl. No.: 14/501,475

(22) Filed: Sep. 30, 2014

(51) Int. Cl. G01R 31/3177

(52) U.S. Cl. CPC G01R 31/3177

(57) ABSTRACT

A pull cell scan flip-flop includes a scan flip-flop and a pull cell. The pull cell is configured to receive a scan flip-flop output signal from the scan flip-flop, the scan flip-flop output signal having a scan flip-flop output value. The pull cell is configured to receive a scan-enable signal and to generate a modified flip-flop output signal. The modified flip-flop output signal has a specified fixed value responsive to the scan-enable signal having a first logic value, and the modified flip-flop output signal has the scan flip-flop output value responsive to the scan-enable signal having a second logic value.

### BACKGROUND

A flip-flop is a digital logic circuit that latches at one of two possible states, such as 0 or 1, to store information for a period of time. Depending upon one or more signals input to the flip-flop, the flip-flop toggles between the states and outputs signals indicative of the states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an illustration of a circuit schematic of at least a portion of a single-pull cell scan flip-flop, in accordance with some embodiments.

FIG. 1B is an illustration of a circuit symbol of at least a portion of a single-pull cell scan flip-flop, in accordance with some embodiments.

FIG. 2A is an illustration of a circuit schematic of at least a portion of a double-pull cell scan flip-flop, in accordance with some embodiments.

FIG. 2B is an illustration of a circuit symbol of at least a portion of a double-pull cell scan flip-flop, in accordance with some embodiments.

FIG. 3 is an illustration of a circuit schematic of at least a portion of a negated AND (NAND) gate, in accordance with some embodiments.

FIG. 4 is an illustration of waveforms, in accordance with some embodiments.

FIG. 5 is an illustration of waveforms, in accordance with some embodiments.

FIG. 6 is an illustration of a circuit schematic of at least a portion of a plurality of single-pull cell scan flip-flops, in accordance with some embodiments.

FIG. 7 is an illustration of a circuit schematic of at least a portion of a plurality of double-pull cell scan flip-flops, in accordance with some embodiments.

FIG. 8 is an illustration of a method of operating a scan flip-flop, in accordance with some embodiments.

FIG. 9 is an illustration of a method of operating a scan flip-flop, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

A scan flip-flop is a type of flip-flop that includes circuitry that allows testing to be performed on the flip-flop. In some embodiments, for testing purposes, the scan flip-flop is coupled with a chain of one or more other scan flip-flops, such as to determine if an error is propagated along the chain during a scan shifting mode of operation. An output of the scan flip-flop is thus coupled with an input of an adjacent scan flip-flop in the chain. The output of the scan flip-flop is also, however, coupled with a combinational circuit that is configured to receive a signal output from the scan flip-flop. When the scan flip-flop operates in the scan-shifting mode of operation for testing purposes, the signal output by the scan flip-flop changes more frequently than when the scan flip-flop operates in a normal or non-scan-shifting mode of operation. In some embodiments, the more frequent change of the signal output causes more transistor switching within the combinational circuit which increases power consumption. According to some embodiments, a pull cell is disposed between the output of the scan flip-flop and an input of the combinational circuit to reduce power consumption by inhibiting variations in the signal output by the scan flip-flop from being received by the combinational circuit during the scan-shifting mode of operation. The scan flip-flop in conjunction with the pull cell is at times referred to as a pull cell scan flip-flop. According to some embodiments, a flip-flop or scan flip-flop is a D type of flip-flop. According to some embodiments, a flip-flop or scan flip-flop is not limited to a D type of flip-flop. According to some embodiments, a flip-flop or scan flip-flop is a type of flip-flop other than a D type of flip-flop.

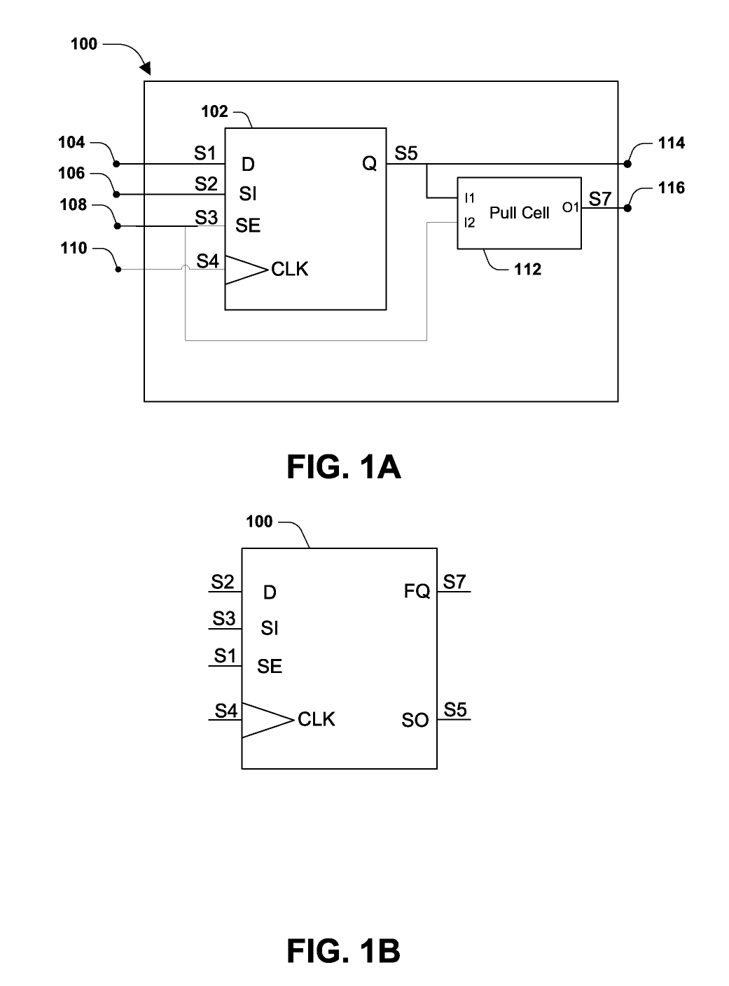

A circuit schematic of a single-pull cell scan flip-flop 100 is illustrated in FIG. 1A, according to some embodiments. In some embodiments, the single-pull cell scan flip-flop 100 comprises a scan flip-flop 102 and a single pull cell 112, hence the name single-pull cell scan flip-flop. In some embodiments, a first node 104 is coupled with a data terminal (D) of the scan flip-flop 102 that is configured to receive a data input signal S1. In some embodiments, a second node 106 is coupled with a scan input terminal (SI) of the scan flip-flop 102 that is configured to receive a scan input signal S2. In some embodiments, a third node 108 is coupled with a scan-enable terminal (SE) of the scan flip-flop 102 that is configured to receive a scan-enable signal S3. In some embodiments, a fourth node 110 is coupled with a clock input terminal (CLK) of the scan flip-flop 102 that is configured to receive a clock signal S4. In some embodiments, a fifth node 114 is coupled with an output terminal (Q) of the scan flip-flop 102 that is configured to provide a scan flip-flop output signal S5 having a scan flip-flop output value. In some embodiments, a first output terminal O1 of the pull cell 112 is coupled with a sixth node 116.

In some embodiments, a first input terminal I1 of the pull cell 112 is coupled with the fifth node 114. In some embodiments, the pull cell 112 is configured to receive the scan flip-flop output signal S5 at the first input terminal I1. In some embodiments, a second input terminal I2 of the pull cell 112 is coupled with the third node 108. In some embodiments, the pull cell 112 is configured to receive the scan-enable signal S3 at the second input terminal I2.

In some embodiments, the pull cell 112 is configured to generate a modified flip-flop output signal S7 at the sixth node 116. In some embodiments, the pull cell 112 is configured to generate the modified flip-flop output signal S7 having a specified fixed value responsive to the scan-enable signal S3 having a first logic value. In some embodiments, the specified fixed value corresponds to 1. In some embodiments, the specified fixed value is 0. In some embodiments, the pull cell 112 is configured to generate the modified flip-flop output signal S7 having the scan flip-flop output value responsive to the scan-enable signal S3 having a second logic value. In some embodiments, the specified fixed value does not correspond to the scan flip-flop output value. In some embodiments, the specified fixed value corresponds to the scan flip-flop output value.

In some embodiments, the first logic value corresponds to a high logic value. In some embodiments, the second logic value corresponds to a low logic value. In some embodiments, the first logic value corresponds to the low logic value. In some embodiments, the second logic value corresponds to the high logic value. In some embodiments, the low logic value corresponds to 0. In some embodiments, the high logic value corresponds to 1.

A circuit symbol of the single-pull cell scan flip-flop 100 is illustrated in FIG. 1B, according to some embodiments. In some embodiments, a data terminal (D) of the single-pull cell scan flip-flop 100 corresponds to the first node 104. In some embodiments, the data terminal (D) of the single-pull cell scan flip-flop 100 is the same as the data terminal (D) of the scan flip-flop 102. In some embodiments, a scan input terminal (SI) of the single-pull cell scan flip-flop 100 corresponds to the second node 106. In some embodiments, the scan input terminal (SI) of the single-pull cell scan flip-flop 100 is the same as the scan input terminal (SI) of the scan flip-flop 102. In some embodiments, a scan-enable terminal (SE) of the single-pull cell scan flip-flop 100 corresponds to the third node 108. In some embodiments, the scan-enable terminal (SE) of the single-pull cell scan flip-flop 100 is the same as the scan-enable terminal (SE) of the scan flip-flop 102. In some embodiments, a clock input terminal (CLK) of the single-pull cell scan flip-flop 100 corresponds to the fourth node 110. In some embodiments, the clock input terminal (CLK) of the single-pull cell scan flip-flop 100 is the same as the clock input terminal (CLK) of the scan flip-flop 102. In some embodiments, a scan output terminal (SO) of the single-pull cell scan flip-flop 100 corresponds to the fifth node 114. In some embodiments, the scan output terminal (SO) of the single-pull cell scan flip-flop 100 is the same as the output terminal (Q) of the scan flip-flop 102. In some embodiments, a fixed output terminal (FQ) of the single-pull cell scan flip-flop 100 corresponds to the sixth node 116. In some embodiments, the fixed output terminal (FQ) of the single-pull cell scan flip-flop 100 is the same as the first output terminal O1 of the pull cell 112.

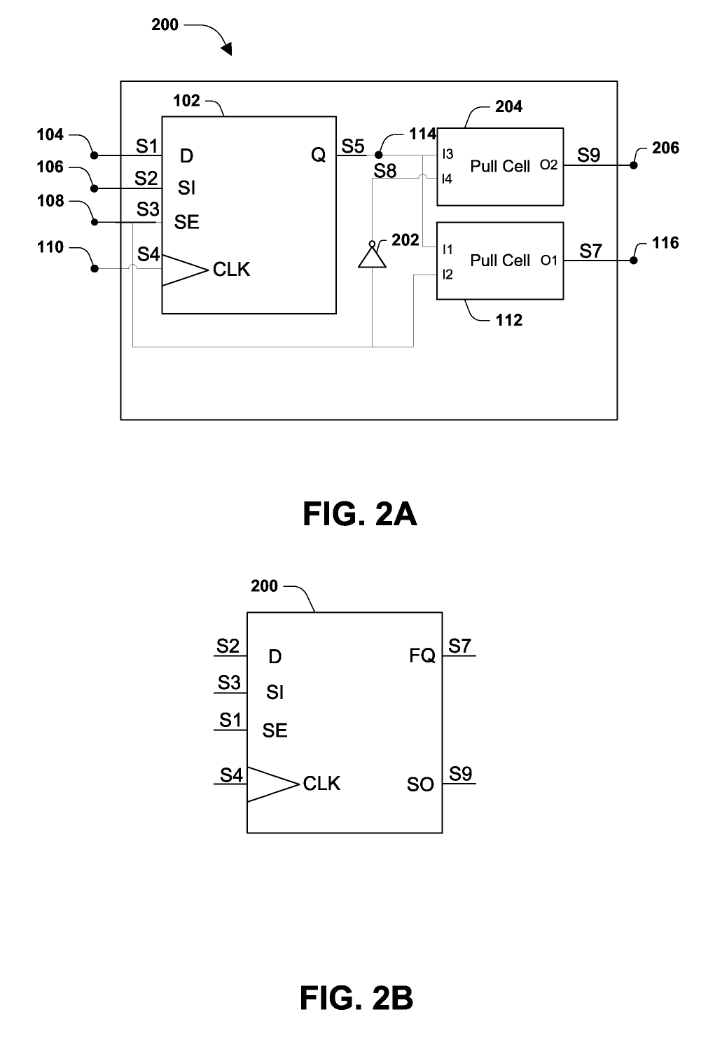

A circuit schematic of a double-pull cell scan flip-flop 200 is illustrated in FIG. 2A, according to some embodiments. In some embodiments, the double-pull cell scan flip-flop 200 comprises the scan flip-flop 102, the pull cell 112 and a second pull cell 204, hence the name double-pull cell scan flip-flop. In some embodiments, the double-pull cell scan flip-flop 200 comprises an inverter 202. In some embodiments, the first node 104 is coupled with the data terminal (D) of the scan flip-flop 102 that is configured to receive the data input signal S1. In some embodiments, the second node 106 is coupled with the scan input terminal (SI) of the scan flip-flop 102 that is configured to receive the scan input signal S2. In some embodiments, the third node 108 is coupled with the scan-enable terminal (SE) of the scan flip-flop 102 that is configured to receive the scan-enable signal S3. In some embodiments, the fourth node 110 is coupled with the clock input terminal (CLK) of the scan flip-flop 102 that is configured to receive the clock signal S4. In some embodiments, the fifth node 114 is coupled with the output terminal (Q) of the scan flip-flop 102 that is configured to output the scan flip-flop output signal S5.

In some embodiments, the first input terminal I1 of the pull cell 112 is coupled with the fifth node 114. In some embodiments, the pull cell 112 is configured to receive the scan flip-flop output signal S5 at the first input terminal I1. In some embodiments, the second input terminal I2 of the pull cell 112 is coupled with the third node 108. In some embodiments, the pull cell 112 is configured to receive the scan-enable signal S3 at the second input terminal I2. In some embodiments, the first output terminal O1 of the pull cell 112 is coupled with the sixth node 116. In some embodiments, the pull cell 112 is configured to generate the modified flip-flop output signal S7 at the sixth node 116. In some embodiments, the pull cell 112 is configured to generate the modified flip-flop output signal S7 having the specified fixed value responsive to the scan-enable signal S3 having the first logic value. In some embodiments, the pull cell 112 is configured to generate the modified flip-flop output signal S7 having the scan flip-flop output value responsive to the scan-enable signal S3 having the second logic value.

In some embodiments, an inverter input of the inverter 202 is coupled with the third node 108. In some embodiments, the inverter 202 is configured to receive the scan-enable signal S3 at the inverter input. In some embodiments, the inverter 202 is configured to generate a scan-enable inverse signal S8 at an inverter output of the inverter 202. In some embodiments, the inverter 202 is configured to generate the scan-enable inverse signal S8 having a first inverter value responsive to the scan-enable signal S3 having the second logic value. In some embodiments, the inverter 202 is configured to generate the scan-enable inverse signal S8 having a second inverter value responsive to the scan-enable signal S3 having the first logic value. In some embodiments, the first inverter value corresponds to the first logic value. In some embodiments, the second logic value corresponds to the second inverter value.

In some embodiments, the second pull cell 204 comprises a third input terminal I3, a fourth input terminal I4 and a second output terminal O2. In some embodiments, the third input terminal I3 is coupled with the fifth node 114. In some embodiments, the second pull cell 204 is configured to receive the scan flip-flop output signal S5 at the third input terminal I3. In some embodiments, the fourth input terminal I4 is coupled with the inverter output of the inverter 202. In some embodiments, the fourth input terminal I4 is configured to receive the scan-enable inverse signal S8 at the fourth input terminal I4. In some embodiments, the second output terminal O2 is coupled with the seventh node 206.

In some embodiments, the second pull cell 204 is configured to generate a modified scan output signal S9 at the seventh node 206. In some embodiments, the second pull cell 204 is configured to generate the modified scan output signal S9 having a second specified fixed value responsive to the scan-enable inverse signal S8 having the first inverter value. In some embodiments, the second pull cell 204 is configured to generate the modified scan output signal S9 having the scan flip-flop output value responsive to the scan-enable inverse signal S8 having the second inverter value. In some embodiments, the second specified fixed value corresponds to the scan flip-flop output value. In some embodiments, the second specified fixed value does not correspond to the scan flip-flop output value.

A circuit symbol of the double-pull cell scan flip-flop 200 is illustrated in FIG. 2B, according to some embodiments. In some embodiments, a data terminal (D) of the double-pull cell scan flip-flop 200 corresponds to the first node 104. In some embodiments, the data terminal (D) of the double-pull cell scan flip-flop 200 is the same as the data terminal (D) of the scan flip-flop 102. In some embodiments, a scan input terminal (SI) of the double-pull cell scan flip-flop 200 corresponds to the second node 106. In some embodiments, the scan input terminal (SI) of the double-pull cell scan flip-flop 200 is the same as the scan input terminal (SI) of the scan flip-flop 102. In some embodiments, a scan-enable terminal (SE) of the double-pull cell scan flip-flop 200 corresponds to the third node 108. In some embodiments, the scan-enable terminal (SE) of the double-pull cell scan flip-flop 200 is the same as the scan-enable terminal (SE) of the scan flip-flop 102. In some embodiments, a clock input terminal (CLK) of the double-pull cell scan flip-flop 200 corresponds to the fourth node 110. In some embodiments, the clock input terminal (CLK) of the double-pull cell scan flip-flop 200 is the same as the clock input terminal (CLK) of the scan flip-flop 102. In some embodiments, a scan output terminal (SO) of the double-pull cell scan flip-flop 200 corresponds to the seventh node 206. In some embodiments, the scan output terminal (SO) of the double-pull cell scan flip-flop 200 is the same as the second output terminal O2 of the second pull cell 204. In some embodiments, a fixed output terminal (FQ) of the double-pull cell scan flip-flop 200 corresponds to the sixth node 116. In some embodiments, the fixed output terminal (FQ) of the double-pull cell scan flip-flop 200 is the same as the first output terminal O1 of the pull cell 112.

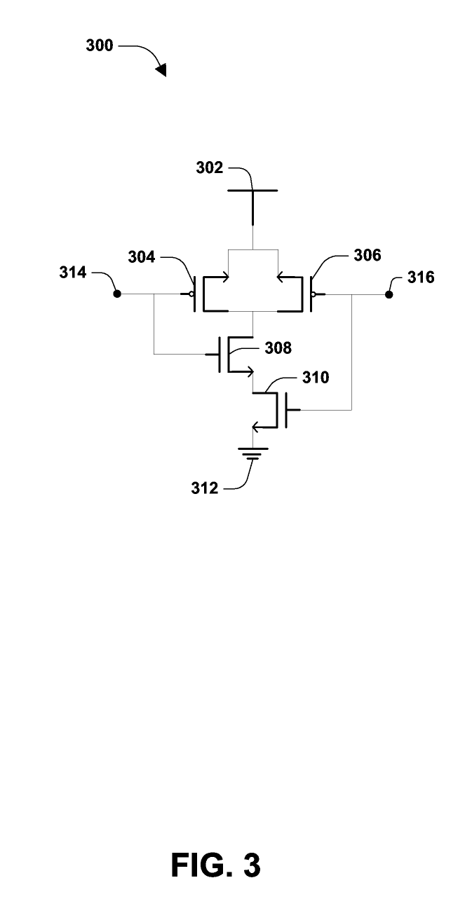

A circuit schematic of a negated AND (NAND) gate 300 is illustrated in FIG. 3, according to some embodiments. In some embodiments, the NAND gate 300 is a combinational circuit that is coupled with a scan flip-flop. In some embodiments, a combinational circuit is a circuit having an output that is a function of one or more inputs. In some embodiments, the NAND gate 300 comprises a plurality of NAND input terminals. In some embodiments, the plurality of NAND input terminals comprises two NAND input terminals. In some embodiments, the plurality of NAND input terminals comprises more than two NAND input terminals. In some embodiments, the NAND gate 300 comprises a first transistor 304, a second transistor 306, a third transistor 308 and a fourth transistor 310. In some embodiments, the NAND gate 300 is an integrated circuit implemented using CMOS technology. In some embodiments, the NAND gate 300 comprises a configuration of one or more metal-oxide-semiconductor field-effect transistors (MOSFETs). In some embodiments, the NAND gate 300 is not implemented using CMOS technology. In this way, in some embodiments, the NAND gate comprises a configuration of one or more transistors that are not MOSFETs. In some embodiments, the first transistor 304 is a p-type MOSFET. In some embodiments, the second transistor 306 is a p-type MOSFET. In some embodiments, the third transistor 308 is an n-type MOSFET. In some embodiments, the fourth transistor 310 is an n-type MOSFET. In some embodiments, a source of the first transistor 304 is coupled with a source of the second transistor 306. In some embodiments, a gate of the first transistor 304 is coupled with a first NAND input terminal 314. In some embodiments, a gate of the second transistor 306 is coupled with a second NAND input terminal 316. In some embodiments, a drain of the first transistor 304 is coupled with a drain of the second transistor 306 and to a drain of the third transistor 308. In some embodiments, a gate of the third transistor 308 is coupled with the first NAND input terminal 314. In some embodiments, a source of the third transistor 308 is coupled with a drain of the fourth transistor 310. In some embodiments, a gate of the fourth transistor 310 is coupled with the second NAND input terminal 316.

In some embodiments, a first voltage source 302 is coupled with the source of the first transistor 304 and to the source of the second transistor 306. In some embodiments, a second voltage source 312 is coupled with a source of the fourth transistor 310. In some embodiments, the first voltage source 302 comprises a power supply configured to provide a constant voltage. In some embodiments, the first voltage source 302 provides a first voltage to the source of the first transistor 304 and to the source of the second transistor 306. In some embodiments, the first voltage is between about 3 V to about 5 V. In some embodiments, the first voltage is below 3 V. In some embodiments, the first voltage is above 5 V. In some embodiments, the second voltage source 312 comprises a power supply configured to provide a constant voltage. In some embodiments, the second voltage source 312 provides a second voltage to the source of the fourth transistor 310. In some embodiments, the second voltage is substantially equal to about 0 V. In some embodiments, the second voltage is between about 0 V and 2 V. In some embodiments, the second voltage is above 2 V.

In some embodiments, the first NAND input terminal 314 is coupled with a scan flip-flop. In some embodiments, the scan flip-flop controls a first NAND input value of a signal at the first NAND input terminal 314. In some embodiments, the first NAND input value switches between the first logic value and the second logic value, based on operations of the scan flip-flop. In some embodiments, the scan flip-flop is the single-pull cell scan flip-flop 100. In some embodiments, the fixed output terminal (FQ) of the single-pull cell scan flip-flop 100 is coupled with the first NAND input terminal 314. In some embodiments, the single-pull cell scan flip-flop 100 is configured to provide the modified flip-flop output signal S7 to the first NAND input terminal 314. In some embodiments, the scan flip-flop is the double-pull cell scan flip-flop 200. In some embodiments, the fixed output terminal (FQ) of the double-pull cell scan flip-flop 200 is coupled with the first NAND input terminal 314. In some embodiments, the double-pull cell scan flip-flop 100 is configured to provide the modified flip-flop output signal S7 to the first NAND input terminal 314.

In some embodiments, the second NAND input terminal 316 is coupled with a scan flip-flop. In some embodiments, the scan flip-flop controls a second NAND input value of a signal at the second NAND input terminal 316. In some embodiments, the second NAND input value switches between the first logic value and the second logic value, based on operations of the scan flip-flop. In some embodiments, the scan flip-flop is the single-pull cell scan flip-flop 100. In some embodiments, the fixed output terminal (FQ) of the single-pull cell scan flip-flop 100 is coupled with the second NAND input terminal 316. In some embodiments, the single-pull cell scan flip-flop 100 is configured to provide the modified flip-flop output signal S7 to the second NAND input terminal 316. In some embodiments, the scan flip-flop is the double-pull cell scan flip-flop 200. In some embodiments, the fixed output terminal (FQ) of the double-pull cell scan flip-flop 200 is coupled with the second NAND input terminal 316. In some embodiments, the double-pull cell scan flip-flop 200 is configured to provide a modified flip-flop output signal S7 to the second NAND input terminal 316.

In some embodiments, responsive to the first NAND input value corresponding to the second logic value the first transistor 304 is configured to be activated. In some embodiments, responsive to the first NAND input value corresponding to the first logic value the first transistor 304 is configured to be deactivated. In some embodiments, responsive to the first NAND input value corresponding to the first logic value the third transistor 308 is configured to be activated. In some embodiments, responsive to the first NAND input value corresponding to the second logic value the third transistor 308 is configured to be deactivated.

In some embodiments, responsive to the second NAND input value corresponding to the second logic value the second transistor 306 is configured to be activated. In some embodiments, responsive to the second NAND input value corresponding to the second logic value the second transistor 306 is configured to be deactivated. In some embodiments, responsive to the second NAND input value corresponding to the second logic value the fourth transistor 310 is configured to be activated. In some embodiments, responsive to the second NAND input value corresponding to the second logic value the fourth transistor 308 is configured to be deactivated.

In some embodiments, a NAND gate leakage current is a function of one or more NAND input values of one or more NAND input terminals of the plurality of NAND input terminals. In some embodiments, the NAND gate leakage current is a function of each NAND input value of every NAND input terminal of the plurality of NAND input terminals. In some embodiments, a NAND gate leakage current is a function of the first NAND input value. In some embodiments, the NAND gate current leakage is a function of the second NAND input value. In some embodiments, the NAND gate leakage current is a total current through the NAND gate from the first voltage source 302 to the second voltage source 312. In some embodiments, when a NAND input value of a signal at a NAND input terminal of the plurality of NAND input terminals corresponds to a NAND minimal leakage value, the NAND gate leakage current is less than when the NAND input value does not correspond to the NAND minimal leakage value. In some embodiments, when the first NAND input value corresponds to the NAND minimal leakage value, the NAND gate leakage current is less than when the first NAND input value does not correspond to the NAND minimal leakage value. In some embodiments, when the second NAND input value corresponds to the NAND minimal leakage value, the NAND gate leakage current is less than when the second NAND input value does not correspond to the NAND minimal leakage value. In some embodiments, the NAND minimal leakage value is 0. In some embodiments, when the first NAND input value is 0 and the second NAND input value is 0, the NAND gate leakage current is about 0.17 nA. In some embodiments, when the first NAND input value is 0 and the second NAND input value corresponds to 1, the NAND gate leakage current is about 22.3 nA. In some embodiments, when the first NAND input value corresponds to 1 and the second NAND input value is 0, the NAND gate leakage current is about 3.77 nA. In some embodiments, when the first NAND input value corresponds to 1 and the second NAND input value corresponds to 1, the NAND gate leakage current is about 41.6 nA.

In some embodiments, a combinational circuit other than a NAND gate comprises a plurality of input terminals. In some embodiments, one or more input terminals of the plurality of input terminals are coupled with one or more scan flip-flops. In some embodiments, a scan flip-flop controls a first input value of a signal at a first input terminal of the plurality of input terminals. In some embodiments, the first input value switches between 1 and 0, based on operations of the scan flip-flop. In some embodiments, the scan flip-flop is the single-pull cell scan flip-flop 100. In some embodiments, the fixed output terminal (FQ) of the single-pull cell scan flip-flop 100 is coupled with the first input terminal. In some embodiments, the single-pull cell scan flip-flop 100 is configured to provide the modified flip-flop output signal S7 to the first input terminal. In some embodiments, the scan flip-flop is the double-pull cell scan flip-flop 200. In some embodiments, the fixed output terminal (FQ) of the double-pull cell scan flip-flop 200 is coupled with the first input terminal. In some embodiments, the double-pull cell scan flip-flop 200 is configured to provide the modified flip-flop output signal S7 to the first input terminal.

In some embodiments, a combinational circuit leakage current is a function of one or more input values of one or more input terminals of the plurality of input terminals. In some embodiments, the combinational circuit leakage current is a function of every input value of every input terminal of the plurality of input terminals. In some embodiments, the combinational circuit leakage current is a function of the first input value. In some embodiments, the combinational circuit leakage current is a total leakage current through the combinational circuit from an eighth node to a ninth node. In some embodiments, the eighth node is coupled with a third voltage source. In some embodiments, the ninth node is coupled with a fourth voltage source. In some embodiments, when an input value of a signal at an input terminal of the plurality of input terminals corresponds to a minimal leakage value, the combinational circuit leakage current is less than when the input value does not correspond to the minimal leakage value. In some embodiments, when the first input value corresponds to the minimal leakage value, the combinational circuit leakage current is less than when the first input value does not correspond to the minimal leakage value.

In some embodiments, in order to determine the minimal leakage value, a combinational circuit leakage current estimate is determined for one or more values of the first input value. In some embodiments, the combinational circuit leakage current estimate is determined for a first value of the first input value and for a second value of the first input value. In some embodiments, the combinational circuit leakage current estimate is determined for one or more combinations of the input values of the input terminals of the plurality of input terminals. In some embodiments, the combinational circuit leakage current estimate is determined by performing a simulation of the combinational circuit. In some embodiments, the simulation is a computer simulation. In some embodiments, the simulation is a physical simulation.

In some embodiments, the combinational circuit is a negated OR (NOR) gate comprising more than two input terminals. In some embodiments, the combinational circuit is a two-input NOR gate comprising the first input terminal and a second input terminal. In some embodiments, the combinational circuit leakage current estimate is determined for every combination of the input values of the input terminals. In some embodiments, a first simulation of the combinational circuit is performed for a first instance where the first input value associated with the first input terminal corresponds to 0 and a second input value associated with the second input terminal corresponds to 0. In some embodiments, based on the first simulation, it is determined that the combinational circuit leakage current estimate is about 44.2 nA for the first instance. In some embodiments, a second simulation of the combinational circuit is performed for a second instance where the first input value corresponds to 0 and the second input value corresponds to 1. In some embodiments, based on the second simulation, it is determined that the combinational circuit leakage current estimate is about 20.4 nA for the second instance. In some embodiments, a third simulation of the combinational circuit is performed for a third instance where the first input value corresponds to 1 and the second input value corresponds to 0. In some embodiments, based on the third simulation, it is determined that the combinational circuit leakage current estimate is about 3.90 nA for the third instance. In some embodiments, a fourth simulation of the combinational circuit is performed for a fourth instance where the first input value corresponds to 1 and the second input value corresponds to 1. In some embodiments, based on the fourth simulation, it is determined that the combinational circuit leakage current estimate is 0.15 nA for the fourth instance. In some embodiments, based on simulation results of the combinational circuit, the minimal leakage value corresponds to 1 in an instance where the combinational circuit is the two-input NOR gate. In some embodiments, the minimal leakage value corresponds to 1 in an instance where the combinational circuit is a NOR gate comprising one or more input terminals.

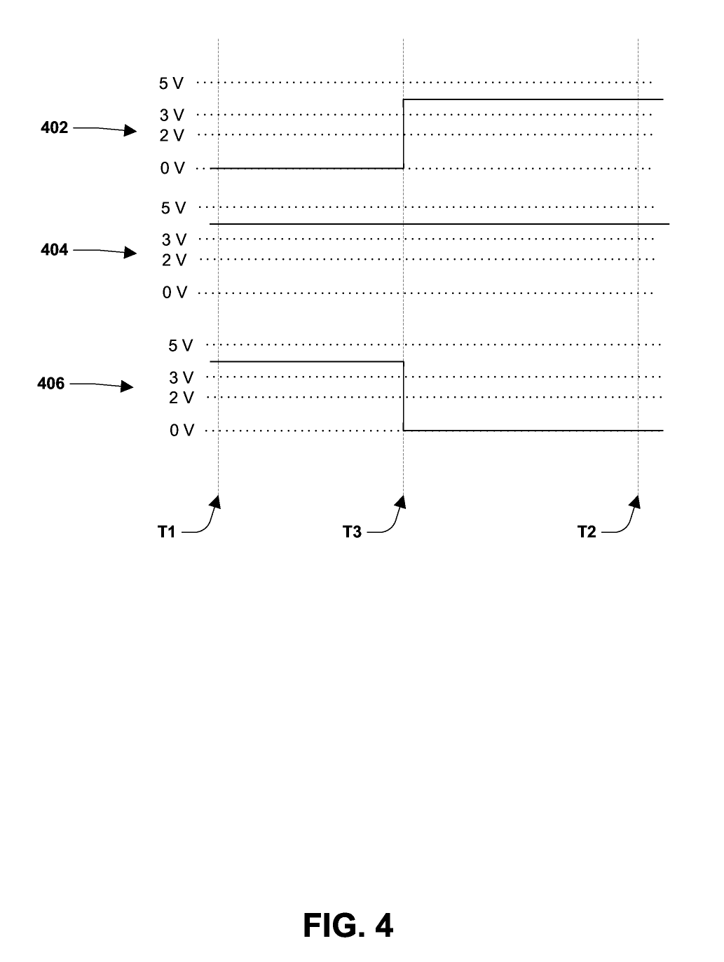

FIG. 4 is an illustration of waveforms corresponding to an example implementation of the single-pull cell scan flip-flop 100. In some embodiments, a first waveform 402 illustrates a scan-enable voltage of the scan-enable signal S3 from a first point in time T1 to a second point in time T2. In some embodiments, a second waveform 404 illustrates a scan output voltage of the scan flip-flop output signal S5 from the first point in time T1 to the second point in time T2. In some embodiments, a third waveform 406 illustrates a modified flip-flop output voltage of the modified flip-flop output signal S7 from the first point in time T1 to the second point in time T2. In some embodiments, the scan-enable signal S3 has the first logic value when the scan-enable voltage is between about 3 V to about 5 V. In some embodiments, the scan-enable signal S3 has the second logic value when the scan-enable voltage is between about 0 V to about 2 V. In some embodiments, the scan flip-flop output signal S5 has the first logic value when the scan output voltage is between about 3 V to about 5 V. In some embodiments, the scan flip-flop output signal S5 has the second logic value when the scan output voltage is between about 0 V to about 2 V. In some embodiments, the modified flip-flop output signal S7 has the first logic value when the modified flip-flop output voltage is between about 3 V to about 5 V. In some embodiments, the modified flip-flop output signal S7 has the second logic value when the modified flip-flop output voltage is between about 0 V to about 2 V.

In some embodiments, at the first point in time T1 the single-pull cell scan flip-flop 100 undergoes normal operation. In some embodiments, at the first point in time T1 the scan-enable signal S3 has the second logic value. In some embodiments, at the first point in time T1 the scan flip-flop output signal S5 has a scan flip-flop output value corresponding to the first logic value. In some embodiments, at the first point in time, responsive to the scan-enable signal S3 having the second logic value the single-pull cell scan flip-flop 100 is configured to generate the modified flip-flop output signal S7 having the scan flip-flop output value. In some embodiments, at the first point in time T1, responsive to the scan flip-flop output value corresponding to the first logic value the modified flip-flop output signal S7 has the first logic value.

In some embodiments, at a third point in time T3 the single-pull cell scan flip-flop 100 begins to undergo a scan-shifting procedure. In some embodiments, at about the third point in time T3 the scan-enable signal S3 changes from having the second logic value to having the first logic value. In some embodiments, at about the third point in time T3 the scan flip-flop output signal S5 has a value that is based on the scan input signal S2. In some embodiments, the value corresponds to the first logic value. In some embodiments, responsive to the scan-enable signal S3 having the first logic value the single-pull cell scan flip-flop 100 generates the modified flip-flop output signal S7 having the specified fixed value. In some embodiments, the specified fixed value corresponds to a minimal leakage value associated with a combinational circuit coupled with the single-pull cell scan flip-flop 100. In some embodiments, the minimal leakage value is 0. In some embodiments, at about the third point in time T3, the modified flip-flop output signal S7 changes from having the first logic value corresponding to 1 to having the second logic value corresponding to 0.

In some embodiments, at the second point in time T2, the single-pull cell scan flip-flop 100 continues to undergo the scan-shifting procedure. In some embodiments, at the second point in time T2, the scan-enable signal S3 has the first logic value. In some embodiments, at the second point in time T2, the scan flip-flop output signal S5 has a value that is based on the scan input signal S2. In some embodiments, at the second point in time T2, the scan flip-flop output signal S5 has a value corresponding to the first logic value. In some embodiments, at the second point in time T2, the modified flip-flop output signal S7 has the fixed value corresponding to the second logic value.

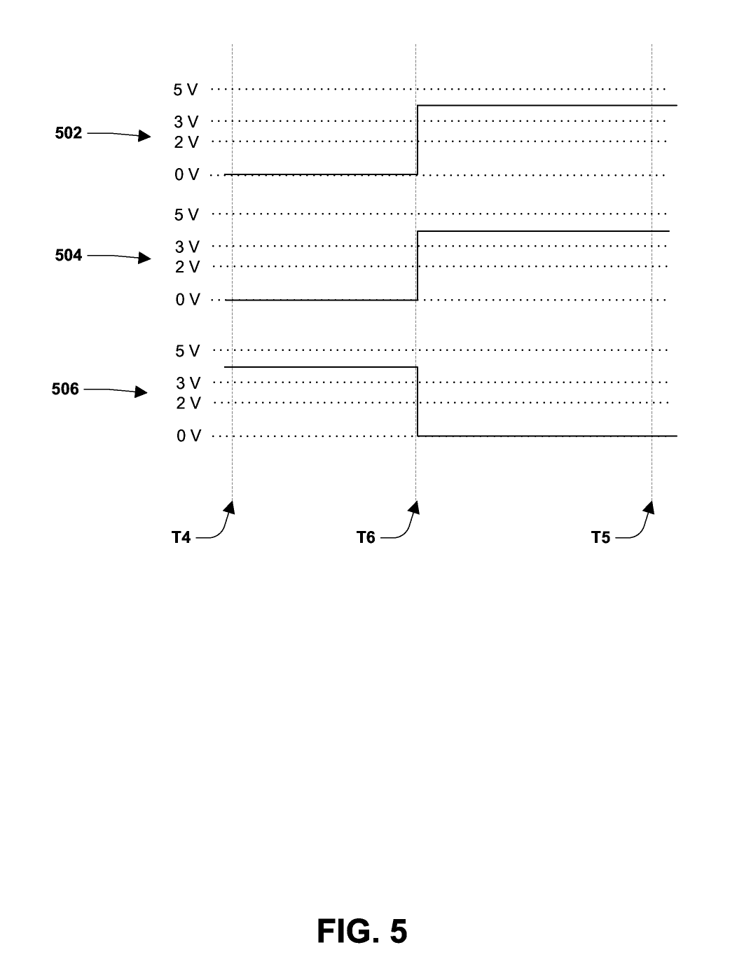

FIG. 5 is an illustration of waveforms corresponding to an example implementation of the double-pull cell scan flip-flop 200. In some embodiments, a fourth waveform 502 illustrates a scan-enable voltage of the scan-enable signal S3 from a fourth point in time T4 to a fifth point in time T5. In some embodiments, a fifth waveform 504 illustrates a modified scan output voltage of the modified scan output signal S9 from the fourth point in time T4 to the fifth point in time T5. In some embodiments, a sixth waveform 506 illustrates the modified flip-flop output voltage of the modified flip-flop output signal S7 from the fourth point in time T4 to the fifth point in time T5. In some embodiments, the scan-enable signal S3 has the first logic value when the scan-enable voltage is between about 3 V to about 5 V. In some embodiments, the scan-enable signal S3 has the second logic value when the scan-enable voltage is between about 0 V to about 2 V. In some embodiments, the modified scan output signal S9 has the first logic value when the modified scan output voltage is between about 3 V to about 5 V. In some embodiments, the modified scan output signal S9 has the second logic value when the modified scan output voltage is between about 0 V to about 2 V. In some embodiments, the modified flip-flop output signal S7 has the first logic value when the modified scan output voltage is between about 3 V to about 5 V. In some embodiments, the modified flip-flop output signal S7 has the second logic value when the scan output voltage is between about 0 V to about 2 V.

In some embodiments, at the fourth point in time T4 the double-pull cell scan flip-flop 200 undergoes normal operation. In some embodiments, at the fourth point in time T4 the scan-enable signal S3 has the second logic value. In some embodiments, at the fourth point in time T4, responsive to the scan-enable signal S3 having the second logic value the modified scan output terminal S9 has the second specified fixed value. In some embodiments, the second specified fixed value corresponds to the second logic value. In some embodiments, at the fourth point in time T4, responsive to the scan-enable signal S3 having the second logic value the double-pull cell scan flip-flop 200 is configured to generate the modified flip-flop output signal S7 having the scan flip-flop output value. In some embodiments, at the fourth point in time T4, the scan flip-flop output value corresponds to the first logic value. In some embodiments, at the fourth point in time T4, responsive to the scan flip-flop output value corresponding to the first logic value the modified flip-flop output signal S7 has the first logic value.

In some embodiments, at a sixth point in time T6 the double-pull cell scan flip-flop 200 begins to undergo a scan-shifting procedure. In some embodiments, at about the sixth point in time T6 the scan-enable signal S3 changes from having the second logic value to having the first logic value. In some embodiments, at about the sixth point in time T6, responsive to the scan-enable signal S3 having the first logic value the modified scan output signal S9 changes from having the value corresponding to the second logic value to having the scan flip-flop output value that is based on the scan input signal S2. In some embodiments, the scan flip-flop output value corresponds to the first logic value. In some embodiments, at about the sixth point in time T6, the modified scan output signal S9 changes from having the second logic value to having the first logic value. In some embodiments, responsive to the scan-enable signal S3 having the first logic value the double-pull cell scan flip-flop 200 generates the modified flip-flop output signal S7 having the specified fixed value. In some embodiments, the specified fixed value corresponds to a minimal leakage value associated with a combinational circuit coupled with the double-pull cell scan flip-flop 200. In some embodiments, the minimal leakage value is 0. In some embodiments, at about the sixth point in time T6, the modified flip-flop output signal S7 changes from having the first logic state to having the second logic state.

In some embodiments, at the fifth point in time T5, the double-pull cell scan flip-flop 200 continues to undergo the scan-shifting procedure. In some embodiments, at the fifth point in time T5, the scan-enable signal S3 has the first logic value. In some embodiments, at the fifth point in time T5, the modified scan output signal S9 has the scan flip-flop output value that is based on the scan input signal S2. In some embodiments, at the fifth point in time T5, the modified scan output signal S9 has a value corresponding to the first logic value. In some embodiments, at the fifth point in time T5, the modified flip-flop output signal S7 has the fixed value corresponding to the second logic value.

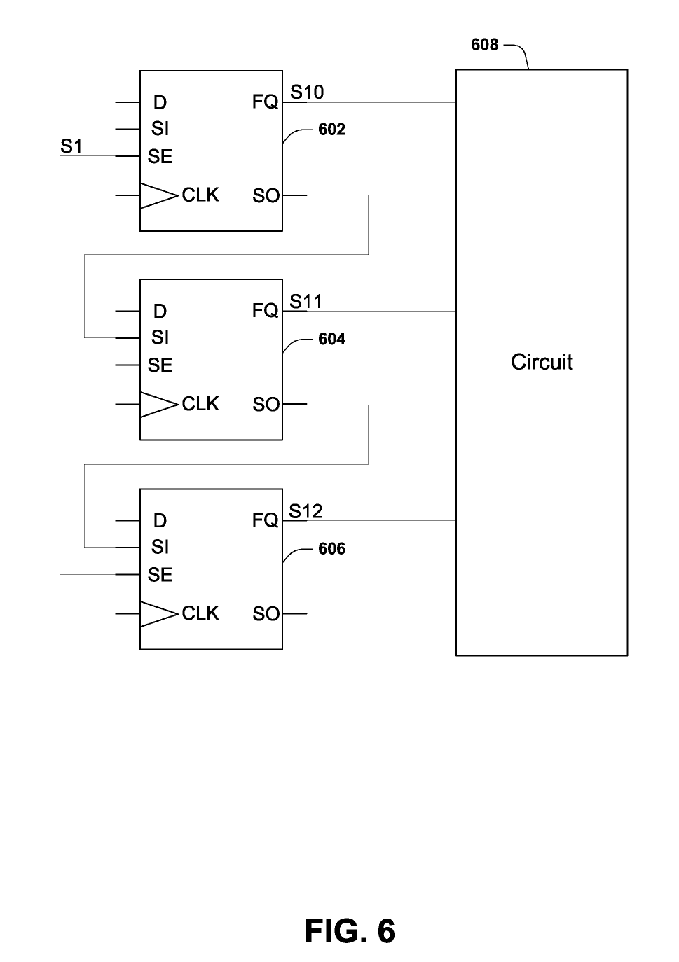

A circuit schematic of a plurality of single-pull cell scan flip-flops is illustrated in FIG. 6, according to some embodiments. In some embodiments, the plurality of single-pull cell scan flip-flops is coupled with a circuit 608, such as one or more combinational circuits. In some embodiments, the plurality of single-pull cell scan flip-flops are coupled in a chain and comprise a first single-pull cell scan flip-flop 602, a second single-pull cell scan flip-flop 604 and a third single-pull cell scan flip-flop 606. In some embodiments, a fixed output terminal (FQ) of the first single-pull cell scan flip-flop 602 is coupled with the circuit 608. In some embodiments, a fixed output terminal (FQ) of the second single-pull cell scan flip-flop 604 is coupled with the circuit 608. In some embodiments, a fixed output terminal (FQ) of the third single-pull cell scan flip-flop 606 is coupled with the circuit 608. In some embodiments, a scan-enable terminal (SE) of the first single-pull cell scan flip-flop 602 is coupled with a scan-enable terminal (SE) of the second single-pull cell scan flip-flop 604. In some embodiments, the scan-enable terminal (SE) of the first single-pull cell scan flip-flop 602 is coupled with a scan-enable terminal (SE) of the third single-pull cell scan flip-flop 606. In some embodiments, the scan-enable terminal (SE) of the second single-pull cell scan flip-flop 604 is coupled with the scan-enable terminal (SE) of the third single-pull cell scan flip-flop 606. In some embodiments, a scan output terminal (SO) of the first single-pull cell scan flip-flop 602 is coupled with a scan input terminal (SI) of the second single-pull cell scan flip-flop 604. In some embodiments, a scan output terminal (SO) of the second single-pull cell scan flip-flop 604 is coupled with a scan input terminal (SI) of the third single-pull cell scan flip-flop 606.

In some embodiments, the plurality of single-pull cell scan flip-flops is configured to undergo a scan-shifting procedure. In some embodiments, during the scan-shifting procedure, a shift register is coupled with a scan input terminal (SI) of the first single-pull cell scan flip-flop 602. In some embodiments, during the scan-shifting procedure, the shift register is coupled with the scan output terminal (SO) of the first single-pull cell scan flip-flop 602. In some embodiments, during the scan-shifting procedure, the shift register is coupled with the scan input terminal (SI) of the second single-pull cell scan flip-flop 604. In some embodiments, during the scan-shifting procedure, the shift register is coupled with the scan output terminal (SO) of the second single-pull cell scan flip-flop 604. In some embodiments, during the scan-shifting procedure, the shift register is coupled with the scan input terminal (SI) of the third single-pull cell scan flip-flop 606. In some embodiments, during the scan-shifting procedure, the shift register is coupled with a scan output terminal (SO) of the third single-pull cell scan flip-flop 606.

In some embodiments, the first single-pull cell scan flip-flop 602 receives the scan-enable signal S3 at the scan-enable terminal (SE) of the first single-pull cell scan flip-flop 602. In some embodiments, the second single-pull cell scan flip-flop 604 receives the scan-enable signal S3 at the scan-enable terminal (SE) of the second single-pull cell scan flip-flop 604. In some embodiments, the third single-pull cell scan flip-flop 606 receives the scan-enable signal S3 at the scan-enable terminal (SE) of the third single-pull cell scan flip-flop 606.

In some embodiments, the first single-pull cell scan flip-flop 602 is configured to generate a first modified flip-flop output signal S10 at the fixed output terminal (FQ) of the first single-pull cell scan flip-flop 602. In some embodiments, the second single-pull cell scan flip-flop 604 is configured to generate a second modified flip-flop output signal S11 at the fixed output terminal (FQ) of the second single-pull cell scan flip-flop 604. In some embodiments, the third single-pull cell scan flip-flop 606 is configured to generate a third modified flip-flop output signal S12 at the fixed output terminal (FQ) of the third single-pull cell scan flip-flop 606.

In some embodiments, the circuit 608 comprises a plurality of components. In some embodiments, the plurality of components comprises a plurality of combinational circuits. In some embodiments, the plurality of combinational circuits comprises a first combinational circuit, a second combinational circuit and a third combinational circuit. In some embodiments, the fixed output terminal (FQ) of the first single-pull cell scan flip-flop 602 is coupled with the first combinational circuit. In some embodiments, the fixed output terminal (FQ) of the second single-pull cell scan flip-flop 604 is coupled with the second combinational circuit. In some embodiments, the fixed output terminal (FQ) of the third single-pull cell scan flip-flop 606 is coupled with the third combinational circuit. In some embodiments, the first combinational circuit is configured to receive the first modified flip-flop output signal S10 at an input terminal of the first combinational circuit. In some embodiments, the second combinational circuit is configured to receive the second modified flip-flop output signal S11 at an input terminal of the second combinational circuit. In some embodiments, the third combinational circuit is configured to receive the third modified flip-flop output signal S12 at an input terminal of the third combinational circuit.

In some embodiments, during the scan-shifting procedure, the scan-enable signal S3 has the first logic value. In some embodiments, responsive to the scan-enable signal S3 having the first logic value the first single-pull cell scan flip-flop 602 is configured to generate the first modified flip-flop output signal S10 having a first fixed value. In some embodiments, the first fixed value does not change during the scan-shifting procedure. In some embodiments, responsive to the generating the first modified flip-flop output signal S10 having the first fixed value a first state of the first combinational circuit does not change during the scan-shifting procedure. In some embodiments, responsive to the first state not changing during the scan-shifting procedure transistor switching within the first combinational circuit is mitigated. In some embodiments, responsive to the transistor switching being mitigated a dynamic power usage of the first combinational circuit is mitigated.

In some embodiments, responsive to the scan-enable signal S3 having the first logic value the second single-pull cell scan flip-flop 604 is configured to generate the second modified flip-flop output signal S11 having a second fixed value. In some embodiments, the second fixed value does not change during the scan-shifting procedure. In some embodiments, responsive to the generating the second modified flip-flop output signal S11 having the second fixed value a second state of the second combinational circuit does not change during the scan-shifting procedure. In some embodiments, responsive to the second state not changing during the scan-shifting procedure a dynamic power usage of the second combinational circuit is mitigated. In some embodiments, the first fixed value is the same as the second fixed value. In some embodiments, the first fixed value is not the same as the second fixed value. In some embodiments, the first fixed value is greater than the second fixed value. In some embodiments, the second fixed value is greater than the first fixed value.

In some embodiments, responsive to the scan-enable signal S3 having the first logic value the third single-pull cell scan flip-flop 606 is configured to generate the third modified flip-flop output signal S12 having a third fixed value. In some embodiments, the third fixed value does not change during the scan-shifting procedure. In some embodiments, responsive to the generating the third modified flip-flop output signal S12 having the third fixed value a third state of the third combinational circuit does not change during the scan-shifting procedure. In some embodiments, responsive to the third state not changing during the scan-shifting procedure a dynamic power usage of the third combinational circuit is mitigated. In some embodiments, the first fixed value is the same as the third fixed value. In some embodiments, the first fixed value is not the same as the third fixed value. In some embodiments, the first fixed value is greater than the third fixed value. In some embodiments, the third fixed value is greater than the first fixed value. In some embodiments, the second fixed value is the same as the third fixed value. In some embodiments, the second fixed value is not the same as the third fixed value. In some embodiments, the second fixed value is greater than the third fixed value. In some embodiments, the third fixed value is greater than the second fixed value.

In some embodiments, the first fixed value corresponds to a first minimal leakage value. In some embodiments, responsive to the first modified flip-flop output signal S10 having the first fixed value corresponding to the first minimal leakage value a leakage current of the first combinational circuit is less than a second leakage current of the first combinational circuit responsive to the first modified flip-flop output signal S10 having the first fixed value not corresponding to the first minimal leakage value. In some embodiments, the first minimal leakage value is 0. In some embodiments, the first minimal leakage value corresponds to 1. In some embodiments, the first combinational circuit is a NAND gate. In some embodiments, if the first combinational circuit is the NAND gate, the first minimal leakage value is 0. In some embodiments, the first combinational circuit is a NOR gate. In some embodiments, if the first combinational circuit is the NOR gate, the first minimal leakage value corresponds to 1. In some embodiments, responsive to the first modified flip-flop output signal S10 having the first fixed value corresponding to the first minimal leakage value a static power usage of the first combinational circuit is mitigated.

In some embodiments, the second fixed value corresponds to a second minimal leakage value. In some embodiments, responsive to the second modified flip-flop output signal S11 having the second fixed value corresponding to the second minimal leakage value a leakage current of the second combinational circuit is less than a second leakage current of the second combinational circuit responsive to the second modified flip-flop output signal S11 having the second fixed value not corresponding to the second minimal leakage value. In some embodiments, the second minimal leakage value is 0. In some embodiments, the second minimal leakage value corresponds to 1. In some embodiments, the second combinational circuit is a NAND gate. In some embodiments, if the second combinational circuit is the NAND gate, the second minimal leakage value is 0. In some embodiments, the second combinational circuit is a NOR gate. In some embodiments, if the second combinational circuit is the NOR gate, the second minimal leakage value corresponds to 1. In some embodiments, responsive to the second modified flip-flop output signal S11 having the second fixed value corresponding to the second minimal leakage value a static power usage of the second combinational circuit is mitigated.

In some embodiments, the third fixed value corresponds to a third minimal leakage value. In some embodiments, responsive to the third modified flip-flop output signal S12 having the third fixed value corresponding to the third minimal leakage value a leakage current of the third combinational circuit is less than a second leakage current of the third combinational circuit responsive to the third modified flip-flop output signal S12 having the third fixed value not corresponding to the third minimal leakage value. In some embodiments, the third minimal leakage value is 0. In some embodiments, the third minimal leakage value corresponds to 1. In some embodiments, the third combinational circuit is a NAND gate. In some embodiments, if the third combinational circuit is the NAND gate, the third minimal leakage value is 0. In some embodiments, the third combinational circuit is a NOR gate. In some embodiments, if the third combinational circuit is the NOR gate, the third minimal leakage value corresponds to 1. In some embodiments, responsive to the third modified flip-flop output signal S12 having the third fixed value corresponding to the third minimal leakage value a static power usage of the third combinational circuit is mitigated.

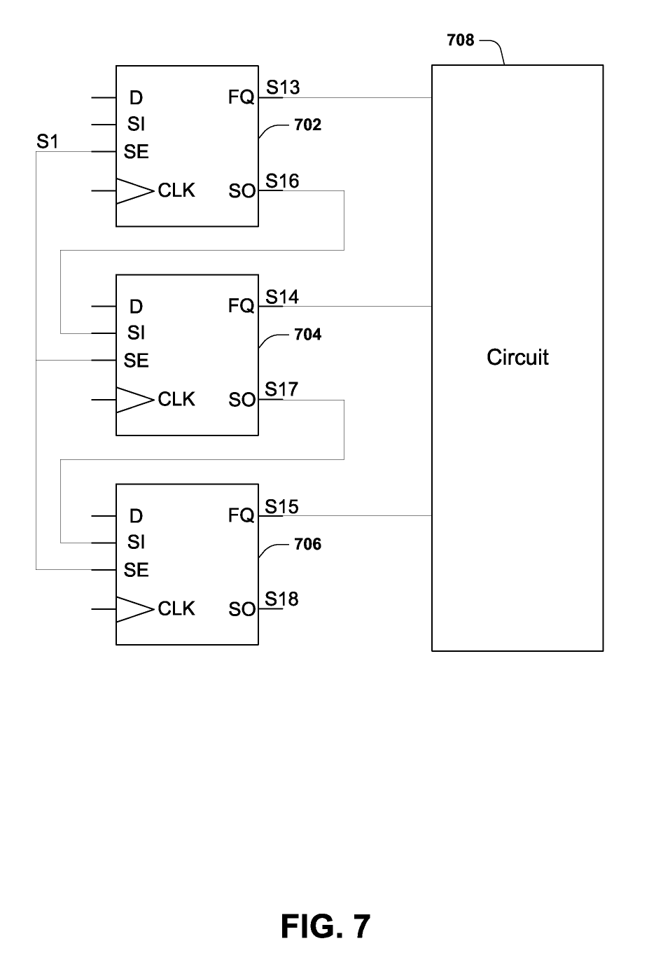

A circuit schematic of a plurality of double-pull cell scan flip-flops is illustrated in FIG. 7, according to some embodiments. In some embodiments, the plurality of double-pull cell scan flip-flops is coupled with a circuit 708, such as one or more combinational circuits. In some embodiments, the plurality of double-pull cell scan flip-flops are coupled in a chain and comprise a first double-pull cell scan flip-flop 702, a second double-pull cell scan flip-flop 704 and a third double-pull cell scan flip-flop 706. In some embodiments, a fixed output terminal (FQ) of the first double-pull cell scan flip-flop 702 is coupled with the circuit 708. In some embodiments, a fixed output terminal (FQ) of the second double-pull cell scan flip-flop 704 is coupled with the circuit 708. In some embodiments, a fixed output terminal (FQ) of the third double-pull cell scan flip-flop 706 is coupled with the circuit 708. In some embodiments, a scan-enable terminal (SE) of the first double-pull cell scan flip-flop 702 is coupled with a scan-enable terminal (SE) of the second double-pull cell scan flip-flop 704. In some embodiments, the scan-enable terminal (SE) of the first double-pull cell scan flip-flop 702 is coupled with a scan-enable terminal (SE) of the third double-pull cell scan flip-flop 706. In some embodiments, the scan-enable terminal (SE) of the second double-pull cell scan flip-flop 704 is coupled with the scan-enable terminal (SE) of the third double-pull cell scan flip-flop 706. In some embodiments, a scan output terminal (SO) of the first double-pull cell scan flip-flop 702 is coupled with a scan input terminal (SI) of the second double-pull cell scan flip-flop 704. In some embodiments, a scan output terminal (SO) of the second double-pull cell scan flip-flop 704 is coupled with a scan input terminal (SI) of the third double-pull cell scan flip-flop 706.

In some embodiments, the plurality of double-pull cell scan flip-flops is configured to undergo a scan-shifting procedure. In some embodiments, during the scan-shifting procedure, a shift register is coupled with a scan input terminal (SI) of the first double-pull cell scan flip-flop 702. In some embodiments, during the scan-shifting procedure, the shift register is coupled with the scan output terminal (SO) of the first double-pull cell scan flip-flop 702. In some embodiments, during the scan-shifting procedure, the shift register is coupled with the scan input terminal (SI) of the second double-pull cell scan flip-flop 704. In some embodiments, during the scan-shifting procedure, the shift register is coupled with the scan output terminal (SO) of the second double-pull cell scan flip-flop 704. In some embodiments, during the scan-shifting procedure, the shift register is coupled with the scan input terminal (SI) of the third double-pull cell scan flip-flop 706. In some embodiments, during the scan-shifting procedure, the shift register is coupled with a scan output terminal (SO) of the third double-pull cell scan flip-flop 706.

In some embodiments, the first double-pull cell scan flip-flop 702 receives the scan-enable signal S3 at the scan-enable terminal (SE) of the first double-pull cell scan flip-flop 702. In some embodiments, the second double-pull cell scan flip-flop 704 receives the scan-enable signal S3 at the scan-enable terminal (SE) of the second double-pull cell scan flip-flop 704. In some embodiments, the third double-pull cell scan flip-flop 706 receives the scan-enable signal S3 at the scan-enable terminal (SE) of the third double-pull cell scan flip-flop 706.

In some embodiments, the first double-pull cell scan flip-flop 702 is configured to generate a fourth modified flip-flop output signal S13 at the fixed output terminal (FQ) of the first double-pull cell scan flip-flop 702. In some embodiments, the second double-pull cell scan flip-flop 704 is configured to generate a fifth modified flip-flop output signal S14 at the fixed output terminal (FQ) of the second double-pull cell scan flip-flop 704. In some embodiments, the third double-pull cell scan flip-flop 706 is configured to generate a sixth modified flip-flop output signal S15 at the fixed output terminal (FQ) of the third double-pull cell scan flip-flop 706.

In some embodiments, the circuit 708 comprises a plurality of components. In some embodiments, the plurality of components comprises a plurality of combinational circuits. In some embodiments, the plurality of combinational circuits comprises a fourth combinational circuit, a fifth combinational circuit and a sixth combinational circuit. In some embodiments, the fixed output terminal (FQ) of the first double-pull cell scan flip-flop 702 is coupled with the fourth combinational circuit. In some embodiments, the fixed output terminal (FQ) of the second double-pull cell scan flip-flop 704 is coupled with the fifth combinational circuit. In some embodiments, the fixed output terminal (FQ) of the third double-pull cell scan flip-flop 706 is coupled with the sixth combinational circuit. In some embodiments, the fourth combinational circuit is configured to receive the fourth modified flip-flop output signal S13 at an input terminal of the fourth combinational circuit. In some embodiments, the fifth combinational circuit is configured to receive the fifth modified flip-flop output signal S14 at an input terminal of the fifth combinational circuit. In some embodiments, the sixth combinational circuit is configured to receive the sixth modified flip-flop output signal S15 at an input terminal of the sixth combinational circuit.

In some embodiments, during the scan-shifting procedure, the scan-enable signal S3 has the first logic value. In some embodiments, responsive to the scan-enable signal S3 having the first logic value the first double-pull cell scan flip-flop 702 is configured to generate the fourth modified flip-flop output signal S13 having a fourth fixed value. In some embodiments, the fourth fixed value does not change during the scan-shifting procedure. In some embodiments, responsive to the generating the fourth modified flip-flop output signal S13 having the fourth fixed value a fourth state of the fourth combinational circuit does not change during the scan-shifting procedure. In some embodiments, responsive to the fourth state not changing during the scan-shifting procedure a dynamic power usage of the fourth combinational circuit is mitigated.

In some embodiments, responsive to the scan-enable signal S3 having the first logic value the second double-pull cell scan flip-flop 704 is configured to generate the fifth modified flip-flop output signal S14 having a fifth fixed value. In some embodiments, the fifth fixed value does not change during the scan-shifting procedure. In some embodiments, responsive to the generating the fifth modified flip-flop output signal S14 having the fifth fixed value a fifth state of the fifth combinational circuit does not change during the scan-shifting procedure. In some embodiments, responsive to the fifth state not changing during the scan-shifting procedure a dynamic power usage of the fifth combinational circuit is mitigated. In some embodiments, the fourth fixed value is the same as the fifth fixed value. In some embodiments, the fourth fixed value is not the same as the fifth fixed value. In some embodiments, the fourth fixed value is greater than the fifth fixed value. In some embodiments, the fifth fixed value is greater than the fourth fixed value.

In some embodiments, responsive to the scan-enable signal S3 having the first logic value the third double-pull cell scan flip-flop 706 is configured to generate the sixth modified flip-flop output signal S15 having a sixth fixed value. In some embodiments, the sixth fixed value does not change during the scan-shifting procedure. In some embodiments, responsive to the generating the sixth modified flip-flop output signal S15 having the sixth fixed value a sixth state of the sixth combinational circuit does not change during the scan-shifting procedure. In some embodiments, responsive to the sixth state not changing during the scan-shifting procedure a dynamic power usage of the sixth combinational circuit is mitigated. In some embodiments, the fourth fixed value is the same as the sixth fixed value. In some embodiments, the fourth fixed value is not the same as the sixth fixed value. In some embodiments, the fourth fixed value is greater than the sixth fixed value. In some embodiments, the sixth fixed value is greater than the fourth fixed value. In some embodiments, the fifth fixed value is the same as the sixth fixed value. In some embodiments, the fifth fixed value is not the same as the sixth fixed value. In some embodiments, the fifth fixed value is greater than the sixth fixed value. In some embodiments, the sixth fixed value is greater than the fifth fixed value.

In some embodiments, the fourth fixed value corresponds to a fourth minimal leakage value. In some embodiments, responsive to the fourth modified flip-flop output signal S13 having the fourth fixed value corresponding to the fourth minimal leakage value a leakage current of the fourth combinational circuit is less than a second leakage current of the fourth combinational circuit responsive to the fourth modified flip-flop output signal S13 having the fourth fixed value not corresponding to the fourth minimal leakage value. In some embodiments, the fourth minimal leakage value is 0. In some embodiments, the fourth minimal leakage value corresponds to 1. In some embodiments, the fourth combinational circuit is a NAND gate. In some embodiments, if the fourth combinational circuit is the NAND gate, the fourth minimal leakage value is 0. In some embodiments, the fourth combinational circuit is a NOR gate. In some embodiments, if the fourth combinational circuit is the NOR gate, the fourth minimal leakage value corresponds to 1. In some embodiments, responsive to the fourth modified flip-flop output signal S13 having the fourth fixed value corresponding to the fourth minimal leakage value a static power usage of the fourth combinational circuit is mitigated.

In some embodiments, the fifth fixed value corresponds to a fifth minimal leakage value. In some embodiments, responsive to the fifth modified flip-flop output signal S14 having the fifth fixed value corresponding to the fifth minimal leakage value a leakage current of the fifth combinational circuit is less than a second leakage current of the fifth combinational circuit responsive to the fifth modified flip-flop output signal S14 having the fifth fixed value not corresponding to the fifth minimal leakage value. In some embodiments, the fifth minimal leakage value is 0. In some embodiments, the fifth minimal leakage value corresponds to 1. In some embodiments, the fifth combinational circuit is a NAND gate. In some embodiments, if the fifth combinational circuit is the NAND gate, the fifth minimal leakage value is 0. In some embodiments, the fifth combinational circuit is a NOR gate. In some embodiments, if the fifth combinational circuit is the NOR gate, the fifth minimal leakage value corresponds to 1. In some embodiments, responsive to the fifth modified flip-flop output signal S14 having the fifth fixed value corresponding to the fifth minimal leakage value a static power usage of the fifth combinational circuit is mitigated.

In some embodiments, the sixth fixed value corresponds to a sixth minimal leakage value. In some embodiments, responsive to the sixth modified flip-flop output signal S15 having the sixth fixed value corresponding to the sixth minimal leakage value a leakage current of the sixth combinational circuit is less than a second leakage current of the sixth combinational circuit responsive to the sixth modified flip-flop output signal S15 having the sixth fixed value not corresponding to the sixth minimal leakage value. In some embodiments, the sixth minimal leakage value is 0. In some embodiments, the sixth minimal leakage value corresponds to 1. In some embodiments, the sixth combinational circuit is a NAND gate. In some embodiments, if the sixth combinational circuit is the NAND gate, the sixth minimal leakage value is 0. In some embodiments, the sixth combinational circuit is a NOR gate. In some embodiments, if the sixth combinational circuit is the NOR gate, the sixth minimal leakage value corresponds to 1. In some embodiments, responsive to the sixth modified flip-flop output signal S15 having the sixth fixed value corresponding to the sixth minimal leakage value a static power usage of the sixth combinational circuit is mitigated.

In some embodiments, responsive to the plurality of double-pull cell scan flip-flops not undergoing the scan-shifting procedure the scan-enable signal S3 has the second logic value. In some embodiments, responsive to the scan-enable signal S3 having the second logic value the first double-pull cell scan flip-flop 702 is configured to generate a first modified scan output signal S16 having a seventh fixed value. In some embodiments, responsive to the generating the first modified scan output signal S16 having the seventh fixed value a dynamic power usage of the plurality of double-pull cell scan flip-flops is mitigated. In some embodiments, the seventh fixed value corresponds to 1. In some embodiments, the seventh fixed value is 0.

In some embodiments, responsive to the scan-enable signal S3 having the second logic value the second double-pull cell scan flip-flop 704 is configured to generate a second modified scan output signal S17 having an eighth fixed value. In some embodiments, responsive to the generating the second modified scan output signal S17 having the eighth fixed value a dynamic power usage of the plurality of double-pull cell scan flip-flops is mitigated. In some embodiments, the eighth fixed value corresponds to 1. In some embodiments, the eighth fixed value is 0.

In some embodiments, responsive to the scan-enable signal S3 having the second logic value the third double-pull cell scan flip-flop 706 is configured to generate a third modified scan output signal S18 having a ninth fixed value. In some embodiments, responsive to the generating the third modified scan output signal S18 having the ninth fixed value a dynamic power usage of the plurality of double-pull cell scan flip-flops is mitigated. In some embodiments, the ninth fixed value corresponds to 1. In some embodiments, the ninth fixed value is 0.

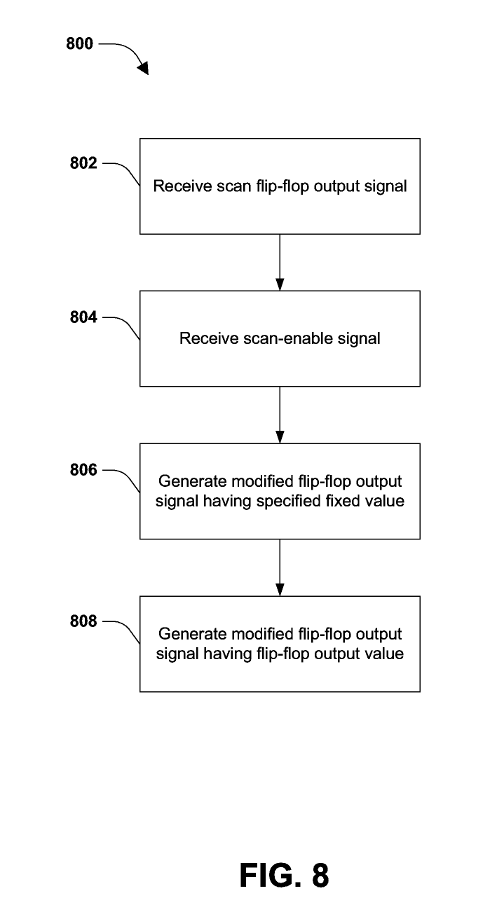

A method 800 of operating a pull cell scan flip-flop is illustrated in FIG. 8, according to some embodiments. In some embodiments, the pull cell scan flip-flop is the single-pull cell scan flip-flop 100. In some embodiments, at 802, the scan flip-flop output signal S5 from the scan flip-flop 102 is received by the pull cell 112. In some embodiments, the scan flip-flop output signal S5 has the scan flip-flop output value. In some embodiments, at 804, the single-pull cell scan flip-flop 100 receives the scan-enable signal S3. In some embodiments, at 806, the single-pull cell scan flip-flop 100 generates the modified flip-flop output signal S7 having the specified fixed value responsive to the scan-enable signal S3 having the first logic value, to mitigate a dynamic power usage of a combinational circuit receiving the modified flip-flop output signal S7. In some embodiments, at 808, the single-pull cell scan flip-flop 100 generates the modified flip-flop output signal S7 having the scan flip-flop output value responsive to the scan-enable signal S3 having the second logic value. In some embodiments, the scan-enable signal S3 has the first logic value responsive to the single-pull cell scan flip-flop 100 undergoing a testing procedure. In some embodiments, the scan enable signal S3 has the second logic value responsive to the single-pull cell scan flip-flop 100 not undergoing the testing procedure.

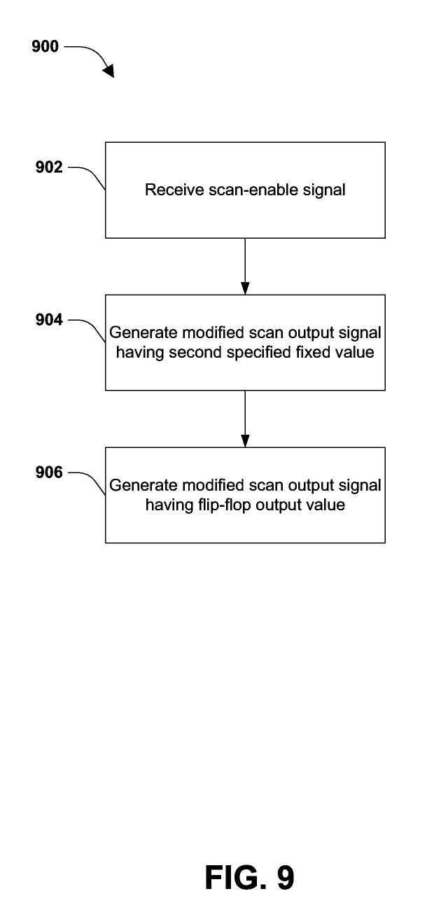

A method 900 of operating a pull cell scan flip-flop is illustrated in FIG. 9, according to some embodiments. In some embodiments, the pull cell scan flip-flop is the double-pull cell scan flip-flop 200. In some embodiments, at 902, the double-pull cell scan flip-flop 200 receives the scan-enable signal S3. In some embodiments, at 904, the double-pull cell scan flip-flop 200 generates the modified scan output signal S9 having the second specified fixed value responsive to the scan-enable signal S3 having the second logic value, to mitigate a power usage. In some embodiments, the power usage is a power usage of a plurality of scan flip-flops comprising the double-pull cell scan flip-flop 200. In some embodiments, at 906, the double-pull cell scan flip-flop 200 generates the modified scan output signal S9 having the scan flip-flop output value responsive to the scan-enable signal S3 having the first logic value. In some embodiments, the scan-enable signal S3 has the first logic value responsive to the double-pull cell scan flip-flop 200 undergoing a testing procedure. In some embodiments, the scan enable signal S3 has the second logic value responsive to the double-pull cell scan flip-flop 200 not undergoing the testing procedure.

In some embodiments, a pull cell scan flip-flop is provided. In some embodiments, the pull cell scan flip-flop comprises a scan flip-flop and a pull cell. In some embodiments, the scan flip-flop comprises an output terminal from which a scan flip-flop output signal is output. In some embodiments, the scan flip-flop output signal has a scan flip-flop output value. In some embodiments, the pull cell comprises a first input terminal and a second input terminal. In some embodiments, the first input terminal is configured to receive the scan flip-flop output signal. In some embodiments, the second input terminal is configured to receive a scan-enable signal. In some embodiments, the pull cell comprises a first output terminal from which a modified flip-flop output signal is output. In some embodiments, the modified flip-flop output signal has a specified fixed value responsive to the scan-enable signal having a first logic value. In some embodiments, the modified flip-flop output signal has the scan flip-flop output value responsive to the scan-enable signal having a second logic value.

In some embodiments, a method of operating a pull cell scan flip-flop is provided. In some embodiments, the method comprises receiving a scan flip-flop output signal having a scan flip-flop output value from a scan flip-flop. In some embodiments, the method comprises receiving a scan-enable signal. In some embodiments, the method comprises generating a modified flip-flop output signal for application to a combinational circuit. In some embodiments, the modified flip-flop output signal has a specified fixed value responsive to the scan-enable signal having a first logic value, to mitigate power usage of the combinational circuit receiving the modified flip-flop output signal. In some embodiments, the modified flip-flop output signal has the scan flip-flop output value responsive to the scan-enable signal having a second logic value.

In some embodiments, a method of operating a pull cell scan flip-flop is provided. In some embodiments, the method comprises receiving a scan-enable signal. In some embodiments, the method comprises generating a modified scan output signal for application to a second pull cell scan flip-flop. In some embodiments, the modified scan output signal has a second specified fixed value responsive to the scan-enable signal having a second logic value. In some embodiments, the modified scan output signal has a scan flip-flop output value responsive to the scan-enable signal having a first logic value.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A pull cell scan flip-flop, comprising:
a scan flip-flop comprising an output terminal from which a scan flip-flop output signal is output, the scan flip-flop output signal having a scan flip-flop output value; and
a pull cell comprising:
a first input terminal configured to receive the scan flip-flop output signal;
a second input terminal configured to receive a scan-enable signal; and
a first output terminal from which a modified flip-flop output signal is output,
the modified flip-flop output signal having a specified fixed value responsive to the scan-enable signal having a first logic value; and
the modified flip-flop output signal having the scan flip-flop output value responsive to the scan-enable signal having a second logic value.

2. The pull cell scan flip-flop of claim 1, the scan flip-flop comprising:
a data terminal configured to receive a data input signal;
a scan input terminal configured to receive a scan input signal;
a scan enable terminal configured to receive the scan-enable signal; and
a clock input terminal configured to receive a clock signal.

3. The pull cell scan flip-flop of claim 1, comprising:
a fixed output terminal coupled with the first output terminal and with a combinational circuit, the specified fixed value corresponding to 0 when the combinational circuit comprises a negated AND (NAND) circuit.

4. The pull cell scan flip-flop of claim 1, comprising:
a fixed output terminal coupled with the first output terminal and with a combinational circuit, the specified fixed value corresponding to 1 when the combinational circuit comprises a negated OR (NOR) circuit.

5. The pull cell scan flip-flop of claim 1, comprising:
a second pull cell comprising:
a third input terminal configured to receive the scan flip-flop output signal;
a fourth input terminal configured to receive a scan-enable inverse signal; and
a second output terminal from which a modified scan output signal is output,
the modified scan output signal having a second specified fixed value responsive to the scan-enable inverse signal having a first inverter value; and
the modified scan output signal having the scan flip-flop output value responsive to the scan-enable signal having a second inverter value.

6. The pull cell scan flip-flop of claim 5, comprising:
an inverter configured to generate the scan-enable inverse signal as a function of the scan-enable signal.

7. The pull cell scan flip-flop of claim 5, the first inverter value corresponding to the first logic value.

8. The pull cell scan flip-flop of claim 5, the second inverter value corresponding to the second logic value.

9. The pull cell scan flip-flop of claim 2, the scan flip-flop output signal a function of at least one of the data input signal or the scan input signal.

10. A method of operating a pull cell scan flip-flop, comprising:
receiving a scan flip-flop output signal having a scan flip-flop output value from a scan flip-flop;
receiving a scan-enable signal; and
generating a modified flip-flop output signal for application to a combinational circuit,
the modified flip-flop output signal having a specified fixed value responsive to the scan-enable signal having a first logic value, to mitigate power usage of the combinational circuit receiving the modified flip-flop output signal; and
the modified flip-flop output signal having the scan flip-flop output value responsive to the scan-enable signal having a second logic value.

11. The method of claim 10, the specified fixed value corresponding to 0 when the combinational circuit comprises a negated AND (NAND) circuit.

12. The method of claim 10, the specified fixed value corresponding to 1 when the combinational circuit comprises a negated OR (NOR) circuit.

13. The method of claim 10, the scan-enable signal having the first logic value responsive to the scan flip-flop undergoing a testing procedure.

14. The method of claim 10, comprising:
generating a modified scan output signal for application to a second pull cell scan flip-flop,
the modified scan output signal having a second specified fixed value responsive to the scan-enable signal having the second logic value; and
the modified scan output signal having the scan flip-flop output value responsive to the scan-enable signal having the first logic value.

15. A method of operating a pull cell scan flip-flop, comprising:
receiving a scan-enable signal; and
generating a modified scan output signal for application to a second pull cell scan flip-flop,
the modified scan output signal having a second specified fixed value responsive to the scan-enable signal having a second logic value; and
the modified scan output signal having a scan flip-flop output value responsive to the scan-enable signal having a first logic value.

16. The method of claim 15, comprising:
generating a modified flip-flop output signal for application to a combinational circuit,
the modified flip-flop output signal having a specified fixed value responsive to the scan-enable signal having the first logic value; and
the modified flip-flop output signal having the scan flip-flop output value responsive to the scan-enable signal having the second logic value.

17. The method of claim 15, the scan-enable signal having the first logic value responsive to a scan flip-flop undergoing a testing procedure.

18. The method of claim 16, the specified fixed value corresponding to 1 when the combinational circuit comprises a negated OR (NOR) circuit.

19. The method of claim 16, the specified fixed value corresponding to 0 when the combinational circuit comprises a negated AND (NAND) circuit.

20. The method of claim 15, the second specified fixed value corresponding to 0.
